(19) United States
(12) Patent Application Publication
(10) Pub. No.: US 2016/0129945 A1
(43) Pub. Date: May 12, 2016

(54) ARRANGEMENT FOR CLOSING AN OPENING IN A VEHICLE WITH A PANE AND A LIGHT-GUIDING SHEET

(71) Applicant: WEBASTO SE, Stockdorf (DE)

(72) Inventor: Michael DEPPE, Eichenau (DE)

(21) Appl. No.: 14/897,487

(22) PCT Filed: Jun. 16, 2014
(86) PCT No.: PCT/EP2014/062556

§ 371 Date: Dec. 10, 2015

(30) Foreign Application Priority Data
Jun. 19, 2013 (DE) 10 2013 010 163.8

(51) Int. Cl. B62D 25/06; H01L 31/0468; B60Q 3/00; G02B 5/20; B60Q 3/02; F21V 8/00

(52) U.S. Cl. CPC B62D 25/06; B60Q 3/0213; G02B 6/0095; B60Q 3/002; G02B 6/0093; G02B 5/208; H01L 31/0468

(57) ABSTRACT

An arrangement for closing an opening in a vehicle roof, the arrangement having a transparent pane. According to one embodiment, arranged on the pane, on an underside of the pane that is facing the passenger compartment, is a light guide film, into which light from a light source of the arrangement can be coupled. The light guide film is formed in such a way that it emits incoupled light into the passenger compartment.

The present invention relates to an arrangement for closing an opening in a vehicle roof according to the preamble of claim 1.

An arrangement of the type in question is known for example from DE 10 2004 007 988 A1.

Known arrangements for closing a vehicle roof that have a transparent pane ensure that daylight can enter the passenger compartment of a vehicle, so that the passenger compartment is better illuminated in comparison with a vehicle roof without a pane.

The object of the present invention is to provide an arrangement for closing an opening in a vehicle roof with a transparent pane, by means of which the illumination of the passenger compartment is further improved.

This object is achieved by an arrangement according to the characterizing part of claim 1.

According to the invention, provided on the pane of the arrangement is a light guide film, which is arranged on an underside of the pane that is facing the passenger compartment. The light guide film offers the major advantage that the transparent pane itself appears as a homogeneous light source, whereby a pleasant ambient illumination of the passenger compartment can be achieved even at night-time or when there is reduced sunlight. This is achieved by light from a light source of the arrangement being coupled into the light guide film. The light guide film is formed and arranged in such a way that it emits the incoupled light into the passenger compartment (12). In this case, use of a light guide film of a transparent or at least partially transparent or translucent form ensures that daylight or external artificial light can still enter the passenger compartment through the transparent pane. An arrangement according to the invention may serve the purpose of rigidly closing the opening in the vehicle roof as solid glazing. It may alternatively be provided that the opening in the vehicle roof is of an openable design, that is to say that the transparent pane is part of a displaceable panel, which is displaceably designed for exposing the opening in the vehicle roof.

The light guide film is part of a film assembly, which is adhesively attached to or laminated on the underside of the pane. This offers the advantage that, apart from the light-guiding function, further functions can also be undertaken by the film assembly, such as for example protection for the light guide film of the film assembly from scratching.

Further preferred designs are provided by the subclaims.

A corresponding film assembly may preferably have an anti-shatter film, so that the film assembly offers not only the illuminating function but also protection for the occupants. This is important in particular because the transparent pane, which may consist of a laminated glass, a single-pane safety glass or else a transparent plastic, can break in the event of an accident. It is then ensured by the anti-shatter film that fragments of the transparent pane (or the complete pane) cannot enter the passenger compartment. In order to improve this protection further, the film assembly including the anti-shatter protective film may be anchored in an edge region of the transparent pane and connected directly or indirectly to the body of the vehicle. For example, the film assembly may be encapsulated in a foam edging and additionally fastened mechanically (with frictional engagement). The anti-shatter protective film is in this case preferably arranged on the side of the film assembly that is facing the passenger compartment, so that for example it also protects the light guide film from scratching.

A corresponding film assembly preferably includes an IR protective film (infrared protective film), which at least partially absorbs or reflects infrared radiation, that is to say thermal radiation. This offers the advantage that the increase in temperature in the passenger compartment caused by sunlight is reduced. The IR protective film is preferably arranged on a side of the film assembly that is facing the pane, that is to say forms the first layer of the film assembly in the direction in which the vehicle roof is viewed.

In a further preferred design of the present invention, solar cells are also provided in the region of the transparent pane. These solar cells may be integrated in the film assembly, organic solar cells being particularly suitable, either applied as a layer to a film of the film assembly, for example by vapor deposition, or as a corresponding film comprising the organic solar cells that is incorporated in the film assembly. Alternatively, crystalline or amorphous solar cells may also be provided, preferably arranged between the film assembly and the transparent pane. This offers the advantage that the crystalline or amorphous solar cells can be laminated together with the film assembly onto the transparent pane. The solar cells are therefore fixed to the transparent pane by means of the film assembly and are protected by the latter.

According to a further advantageous design of the present invention, a light-incoupling device is provided, by means of which the light from the light source of the arrangement can be coupled into the light guide film. Depending on the type of light source, which is preferably an electrical light source in the form of at least one lamp or LED, such a light-incoupling device may comprise for example lenses for focusing the light onto a side edge of the light guide film. This offers the advantage that the light from such divergent light sources is coupled more efficiently into the light guide film. The light-incoupling device may additionally or alternatively also have prisms or prism couplers in order to couple the light into the light guide film.

The light guide film is formed in such a way that it couples incoupled light out in the direction of the passenger compartment.

In this case, the light guide film may in particular be formed in such a way that rays of light that run within the light guide film in a direction away from the passenger compartment are predominantly reflected by the boundary surface of the light guide film or of a light guide within the light guide film that is facing away from the passenger compartment. The light guide film may also preferably be formed in such a way that rays of light that run within the light guide film (or a light guide within the light guide film) in a direction toward the passenger compartment or parallel to the light guide film are predominantly transmitted by the boundary surface of the light guide film that is facing the passenger compartment. This behavior of the light guide film, that is to say the reflection of the visible light at the surface of the light guide film that is facing away from the passenger compartment back into the light guide film and the transmission of the visible light through the surface of the light guide film that is assigned to the passenger compartment out from the light guide film, leads to a specific illumination of the passenger compartment. This can be achieved by designing the conditions at the outer surface of a light guide of the light guide film in such a way that the angle of total reflection for visible light is as great as possible. This angle of total reflection, which corresponds to the angle of incidence (in relation to the perpendicular axis of incidence) at which a ray of light runs parallel to the boundary surface, is fixed by the refractive indexes on the one hand within the light guide of the light guide film and on the other hand of the optical material that lies alongside the light guide. Corresponding light guide films that reflect as efficiently as possible light which is supposed to be “trapped” in the light guide film on one side, for example the side of the light guide film that is arranged facing away from the passenger compartment, are known. However, in order that the light coupled into the light guide film is not only reflected toward the passenger compartment but is also outcoupled toward it, it may for example be provided that the surface of the light guide that is assigned to the passenger compartment has a structure, such as for example a prism structure, to improve the coupling of light into the passenger compartment. Also or alternatively, diffusers that intensify the radiation of light into the passenger compartment may be provided in the light guide film. Since the boundary surface of the light guide film that is facing the passenger compartment is designed in such a way that the condition for total reflection is not satisfied for a large angular range of angles of incidence of light to the perpendicular of the boundary surface, altogether a large proportion of the incoupled light is directed toward the passenger compartment.

While in principle various light sources, such as incandescent lamps, may be provided as the light source, the design of the arrangement with at least one LED (light-emitting diode) is particularly preferred, since then on the one hand the development of heat by the light source and on the other hand the power consumption by the light source is reduced.

The light source is preferably arranged in the region of an edge of the pane. If a foam edging is provided on the pane, the light source may be integrated in this foam edging. It is in principle of advantage if the light source has a preferred direction of emission, and is installed with such an alignment that this direction of emission is already aligned with the lateral edge of the light guide film. This means that the light source is aligned with its maximum direction of emission parallel to the light guide film and facing the side edge thereof.

The invention is explained in more detail below by way of example on the basis of the accompanying drawings, in which

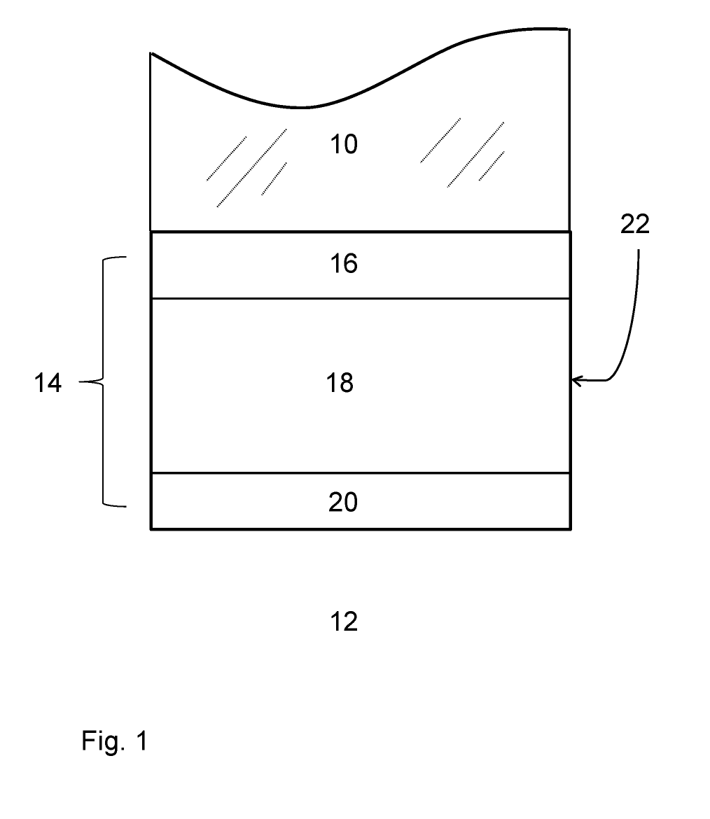

FIG. 1 shows a cross section through a film assembly, as it is arranged on the transparent pane of an arrangement according to the invention.

FIG. 1 shows a transparent pane 10 of an arrangement for closing an opening in a vehicle roof. The pane 10 may in this case be made of glass (single-pane safety glass, toughened glass or laminated glass) or of a transparent plastic, such as for example acrylic. The arrangement depicted closes an opening in a vehicle roof, the passenger compartment 12 of the vehicle lying in the lower region of the image. According to the invention, a film assembly 14 is arranged underneath the transparent pane 10, that is to say for example it is attached or laminated on. A corresponding adhesive between the film assembly 14 and the pane 10 is not represented. The adhesive may for example be introduced by means of a hotmelt adhesive film. The film assembly 14 consists of a sequence of layers from the transparent pane 10 to the passenger compartment 12 comprising an IR reflective or absorbent IR protective film 16, a light guide film 18 (preferably of plastic) and an anti-shatter protective film 20. The IR protective film 16 serves in this case for reducing the extent to which the passenger compartment 12 is heated up by sunlight. The anti-shatter protective film 20, facing the passenger compartment 12, serves on the one hand for protecting the occupants of the vehicle from fragments that may become detached from the transparent pane 10 in the event of an accident. On the other hand, the anti-shatter protective film 20 also serves for protecting the light guide film 18 and the IR protective film 16 from scratching. For this purpose, the anti-shatter protective film 20 may be designed with a scratch-resistant coating. The anti-shatter protective film may also be formed as a single layer and, as a result of its consistency, perform both the anti-shatter function and the scratch-resistant function. It may alternatively also be formed as multiple layers, in order to optimize the anti-shatter protection, or provide or supplement the anti-shatter protection with the scratch resistance.

According to the invention, the illumination of the passenger compartment takes place by a light source (not represented in FIG. 1) of which the light is coupled into the light guide film 18 laterally, that is to say from the left or the right or from both sides in the viewing direction. The light, for example from LEDs or one or more incandescent lamps, is in this case focused onto or coupled into a side face or side edge 22 of the light guide film 18 by way of lenses or prisms. The incoupling may also take place from two opposite side edges. If light is only incoupled from one side edge 22, the opposite side edge may be formed in such a way that it reflects visible light, in order that the trapped light cannot escape here. Alternatively, a separate mirror element may also be provided for this purpose.

The light guide film 18 is formed in such a way that its upper surface (facing the pane 10) reflects incoupled light as efficiently as possible. Conversely, its lower surface (that is to say the surface facing the passenger compartment 12) is formed in such a way that incoupled light is transmitted, that is to say outcoupled, as efficiently as possible toward the passenger compartment 12. In order that the outcoupled light actually reaches the passenger compartment 12, the anti-shatter protective film 20 is of a transparent or translucent form. In order that light can still enter the passenger compartment 12 through the arrangement from the outside, that is to say in FIG. 1 from above, the IR protective film 16 and the light guide film 18 are also of a transparent or translucent form. This ensures that daylight illuminates the passenger compartment 12 through the arrangement. Conversely, the light-guiding plastic film makes an area-covering, homogeneous and ambient illumination of the passenger compartment 12 with artificial light possible.

### LIST OF DESIGNATIONS

10 anti-shatter protective film
12 passenger compartment
14 film assembly
16 IR protective film
18 light guide film
20 anti-shatter protective film
22 side edge of 18

1. An arrangement for closing an opening in a vehicle roof, the arrangement comprising: a transparent pane,
wherein
arranged on the pane, on an underside of the pane that is facing the passenger compartment, is a light guide film, into which light from a light source of the arrangement can be coupled, and which is formed in such a way that it emits the incoupled light into the passenger compartment, the light guide film being part of a film assembly, which is adhesively attached on or laminated to the underside of the pane.

2. The arrangement as claimed in claim 1, wherein the film assembly has an anti-shatter protective film.

3. The arrangement as claimed in claim 2, wherein the anti-shatter protective film is arranged on the side of the film assembly that is facing the passenger compartment.

4. The arrangement as claimed in claim 1, wherein the film assembly has an IR protective film, which at least partially absorbs or reflects IR radiation, the IR protective film preferably being arranged on a side of the film assembly that is facing the pane.

5. The arrangement as claimed in claim 1, wherein the film assembly has a layer or a film that comprises organic solar cells.

6. The arrangement as claimed in claim 1, wherein crystalline or amorphous solar cells are arranged between the film assembly and the pane.

7. The arrangement as claimed in claim 1, wherein a light-incoupling device is provided, by means of which the light from the light source can be coupled into a side edge of the light guide film, and the light guide film is formed in such a way that it couples the incoupled light out in the direction of the passenger compartment.

8. The arrangement as claimed in claim 7, wherein the light guide film is formed in such a way that rays of light that run within the light guide film in a direction away from the passenger compartment are predominantly reflected by the boundary surface of the light guide film that is facing away from the passenger compartment, and rays of light that run within the light guide film in a direction toward the passenger compartment or parallel to the light guide film are transmitted by the boundary surface of the light guide film that is facing the passenger compartment into the passenger compartment.

9. The arrangement as claimed in claim 7, wherein the light source has at least one LED.

10. The arrangement as claimed in claim 7, wherein the light source is arranged in the region of an edge of the pane, preferably in a foam edging of the pane.
